(19) United States
(12) Patent Application Publication
(10) Pub. No.: US 2005/0009356 A1
(43) Pub. Date: Jan. 13, 2005

(54) Method of manufacturing semiconductor device and method of cleaning plasma etching apparatus used therefor

(76) Inventors: Akihiro Kojima, Kanagawa (JP); Junko Ohuchi, Kanagawa (JP); Hisataka Hayashi, Kanagawa (JP)

Correspondence Address: Finnegan, Henderson, Farabow;Garrett & Dunner, L.L.P., 1300 I Street, N.W., Washington, DC, 20005-3315, US

(21) Appl. No.: 10/843,508

(22) Filed: May 12, 2004

(30) Foreign Application Priority Data
May 13, 2003 (JP) 2003-134714
Mar. 31, 2004 (JP) 2004-105896

(51) Int. Cl. H01L 21/4763

(52) U.S. Cl. 438/700

(57) ABSTRACT

A method of manufacturing a semiconductor device according to an aspect of the present invention includes: forming a low-k dielectric film above a semiconductor substrate; forming a resist pattern above the low-k dielectric film; etching the low-k dielectric film using the resist pattern as a mask; and stripping the resist pattern by plasma processing using ammonium ions.

### CROSS-REFERENCE TO RELATED APPLICATION

This application is based upon and claims the benefit of priority from prior Japanese Patent Application Nos. 2003-134714, and 2004-105896 filed on May 13, 2003, and Mar. 31, 2004 in Japan, the entire contents of which are incorporated herein by reference.

### BACKGROUND OF THE INVENTION

1. Field of the Invention

The present invention relates to a method of manufacturing a semiconductor device including a low-k interlayer dielectric film, and a method of cleaning a plasma etching apparatus used in this manufacturing method.

2. Related Art

Recently, the higher integration and faster speed of semiconductor devices have been created a demand for a decrease in capacitance between wiring lines. In order to meet this demand, it is necessary to develop techniques for decreasing the resistance of metal wiring lines, and decreasing the dielectric constant of interlayer dielectric films.

Generally, in order to decrease the resistance of metal wiring lines, a wiring material having a lower specific resistance, such as Cu, is used.

On the other hand, in order to decrease the dielectric constant of interlayer dielectric films, a SiO₂ layer or an FSG (Fluoro-Silicate Glass) layer formed by a plasma CVD (Chemical Vapor Deposition) method has been conventionally used as an interlayer dielectric film. However, the decrease in dielectric constant using such layers is limited from the viewpoint of stability of layer characteristics. As a result, the change in the relative dielectric constant from 4.1 to 3.3 has been the limit.

In order to decrease the relative dielectric constant to 3.0 or lower, a low-k dielectric film formed of, e.g., methylsiloxane (methylpolysiloxane), by a coating method or a CVD method has been studied. Generally, such a material contains carbon or hydrogen as a main ingredient, and has a relatively lower layer density, as compared with a silicon thermally-oxidized film.

Generally, the processing of such a low-k dielectric film is performed using a patterned resist layer as a mask, and thereafter the resist layer is stripped (removed) by the use of oxygen plasma. However, there is a problem in that the oxygen plasma processing changes the properties of the carbon constituent of the exposed low-k dielectric film, thereby increasing the dielectric constant thereof. As a result, the characteristics of such a low-k material cannot be effectively used. When a low-k dielectric film is formed of methylsiloxane, the methyl groups in the methylsiloxane layer are decreased, thereby changing the properties of the layer due to the dehydration condensation reaction.

### SUMMARY OF THE INVENTION

A method of manufacturing a semiconductor device according to a first aspect of the present invention includes: forming a low-k dielectric film above a semiconductor substrate; forming a resist pattern above the low-k dielectric film; etching the low-k dielectric film using the resist pattern as a mask; and stripping the resist pattern by plasma processing using ammonium ions.

A method of manufacturing a semiconductor device according to a second aspect of the present invention includes: forming a low-k dielectric film above a semiconductor substrate; forming a resist pattern above the low-k dielectric film; etching the low-k dielectric film using the resist pattern as a mask; and stripping the resist pattern by plasma processing using nitrogen active species obtained by exciting a nitrogen compound gas selected from the group consisting of NH₃ and HCN by using plasma, an electron density of the plasma being 1×10¹¹ cm⁻³ or less.

A method of cleaning a plasma etching apparatus according to a third aspect of the present invention, in which a resist formed on a surface of a substrate is stripped by plasma etching performed in a vacuum chamber, includes: supplying NH₃ gas to the vacuum chamber; and generating plasma in the vacuum chamber and removing deposits adhering to the inside of the vacuum chamber.

### BRIEF DESCRIPTION OF THE DRAWINGS

FIGS. 1A and 1B are sectional views showing steps of a method of manufacturing a semiconductor device according to the first embodiment of the present invention.

FIGS. 2A to 2C are sectional views showing further steps of the method of manufacturing a semiconductor device according to the first embodiment of the present invention.

FIG. 3 shows the resist stripping rate during a resist stripping step using N₂, H₂, or NH₃ gas.

FIGS. 4A and 4B are sectional views showing steps of a method of manufacturing a semiconductor device according to a first modified example of the first embodiment of the present invention.

FIGS. 5A and 5B are sectional views showing further steps of the method of manufacturing a semiconductor device according to the first modified example of the first embodiment of the present invention.

FIG. 6 shows the structure of a semiconductor device according to a second modified example of the first embodiment of the present invention.

FIG. 7 shows the characteristics of the plasma luminance intensity and the plasma intensity ratio relative to the electron density for explaining a method of manufacturing a semiconductor device according to the second embodiment of the present invention.

FIG. 8 schematically shows the structure of a plasma etching apparatus used in the third embodiment of the present invention.

FIG. 9 shows the relationship between the cleaning time and the resist ashing rate.

FIG. 10 shows the resist stripping rate in the process of performing resist stripping using a gas mixture containing H₂ gas and N₂ gas.

### DESCRIPTION OF THE EMBODIMENTS

First, before the embodiments of the present invention are described, the course of events before the present inventor reached the present invention will be described.

In order to avoid the degradation of the characteristics of a low-k material, a method is proposed for stripping a resist by performing plasma processing using a N₂/H₂ gas mixture containing hydrogen and oxygen instead of the oxygen plasma processing, as shown in, e.g., Japanese Patent Laid-Open Publication No. 2002-261092.

In this case, the following reaction between methylsiloxane and H₂ occurs:
O≡Si—CH₃+2H→O≡Si—H+CH₄.

Furthermore, the following reaction between methylsiloxane and N₂ occurs:
O≡Si—CH₃+N→O≡Si—C—NH₂ or O≡Si—NH₂+HCN.

That is to say, because of the reaction with H₂, methylsiloxane loses a Si—CH₃ bond and creates a Si—H bond, thereby losing the moisture-absorption property. As a result, a problem arises in that the layer easily contains Si—O bonds converted from Si—CH₃ bonds.

In the reaction between methylsiloxane and N₂, the Si—C bond is maintained, or a Si—N bond is newly created. As a result, the layer does not contain Si—O bonds converted from Si—CH₃ bonds.

In the resist removing process, N₂ is dissociated to be N radicals (hereinafter referred to as “N*”), and the resist containing carbon reacts with the N radicals (C+2N*→CN₂), thereby removing the resist.

However, since the bond energy of the N—N bond and the C—N bond is 9.8 eV and 6.3 eV, respectively, the chances are higher that N —N bonds are created, which would eventually constitute N₂ again, than that C—N bonds are created to strip the resist. Thus, the speed of stripping the resist by the use of N₂ is rather slow, i.e., about 90 nm/min. This is not practical for use.

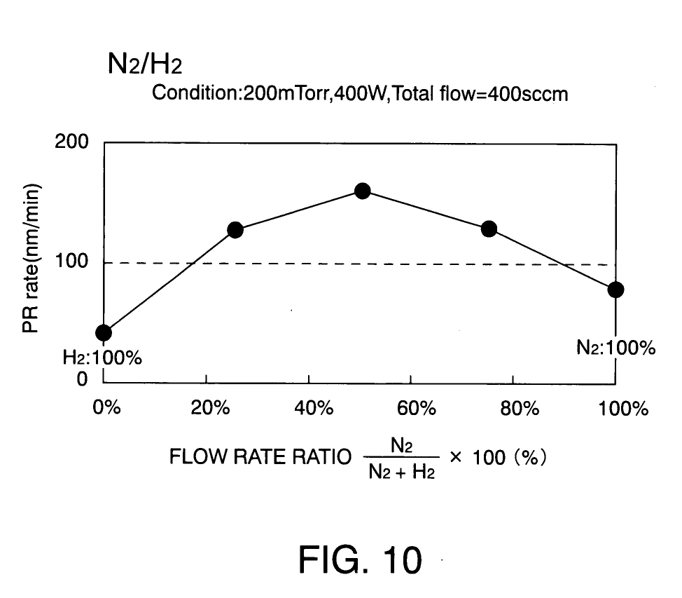

FIG. 10 specifically shows the relationship between the mixture ratio of N₂/H₂ mixture gas and the rate of stripping the resist (PR rate). In FIG. 10, the horizontal axis represents the mixture ratio of a N₂/H₂ gas mixture, and the vertical axis represents the rate of stripping the resist. The point 0% on the horizontal axis means H₂ 100%, and the point 100% means N₂ 100%. The resist stripping conditions in this case are: the pressure of 0.2 Torr; the high frequency power of 400 W; and the total volume 400 sccm of N₂ gas and H₂ gas.

As can be understood from FIG. 10, with respect to the N₂/H₂ mixture gas, the highest rate of stripping the resist can be obtained when the ratio of N₂ to H₂ is about 50% to 50%. However, even on such an occasion, the rate is 150 nm/min., which is not efficient. Furthermore, since the gas mixture contains H₂ gas, the aforementioned reaction occurs between methylsiloxane and H₂, thereby producing a considerable adverse effect of changing the properties.

Hereinafter, embodiments of the present invention will be described with reference to the accompanying drawings.

(First Embodiment)

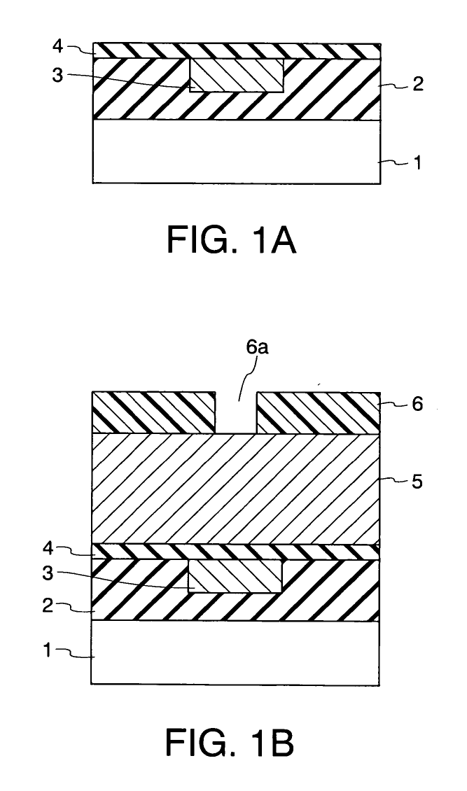

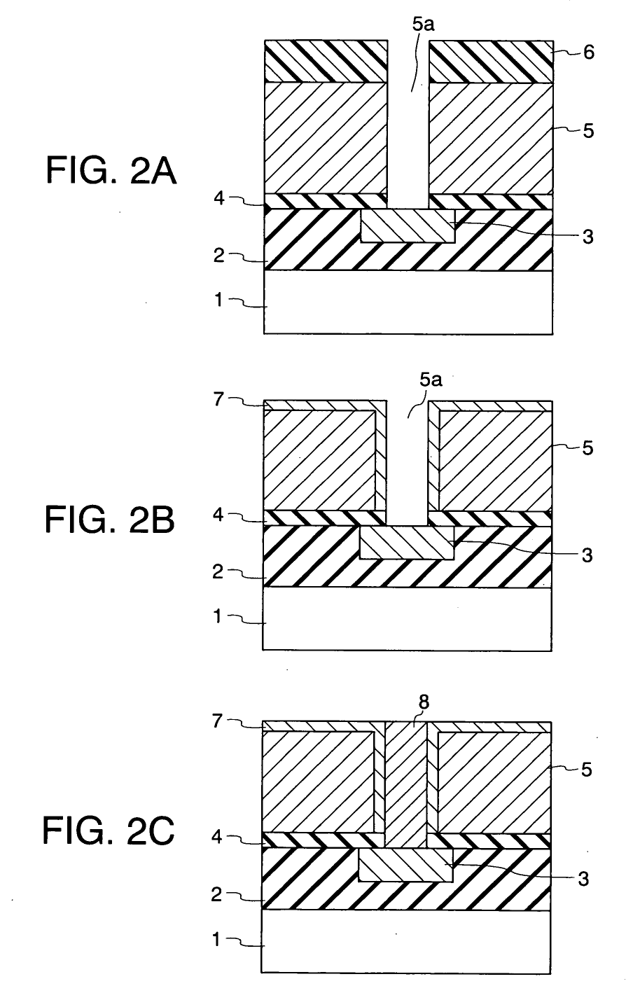

FIGS. 1A to 2C are sectional views showing steps of a method of manufacturing a semiconductor device according to the first embodiment of the present invention.

As shown in FIG. 1A, a first interlayer dielectric film 2 is deposited on a semiconductor substrate 1 in which semiconductor elements (not shown in the drawing) are formed, and an underlayer wiring line 3 of, e.g., Cu, is formed in the first interlayer dielectric film 2. Thereafter, a SiC layer 4 having a thickness of about 35 nm is formed on the wiring line 3 and the first interlayer dielectric film 2 by a CVD method in order to prevent the diffusion of Cu.

Subsequently, as shown in FIG. 1B, methylsiloxane (methylpolysiloxane) is coated on the SiC layer 4 in a thickness of about 500 nm so as to form a low-k dielectric film serving as a second interlayer dielectric film on the SiC layer 4. Thereafter, a heat treatment is performed at a temperature of about 350° C. for about 15 minutes, thereby forming a methylsiloxane layer 5. Then, a resist is coated on the methylsiloxane layer 5 and patterned, thereby forming a resist pattern 6 having an opening 6a. Here, a low-k dielectric film means a dielectric film having a relative dielectric constant of 3.0 or less.

Thereafter, the methylsiloxane layer 5 is etched by an RIE (Reactive Ion Etching) method, using the resist pattern 6 as a mask, thereby forming an opening therethrough, at the bottom of which the SiC layer 4 is exposed. The etching of the methylsiloxane layer 5 is performed by using, e.g., a parallel flat plate type plasma etching apparatus, with the gas flow rates of C₄F₈, Ar, and N₂ being 10, 1,000, and 200 sccm, respectively, the pressure being 100 mTorr, the high frequency power being 1,500 W, and the temperature being 40° C. These etching conditions are only by way of examples, and are not limited to these values. Then, the SiC layer 4 is etched by an RIE method using the resist pattern 6 as a mask, thereby forming a via hole 5a reaching the underlayer wiring line 3, as shown in FIG. 2A.

Next, the resist pattern 6, which is now not necessary, is stripped by plasma processing using NH₃ gas. The stripping of the resist can be performed by, for example, a magnetron RIE apparatus having an electrode to which the workpiece is fixed, and an opposing electrode. The magnetron RIE apparatus includes a vacuum chamber to which NH₃ gas can be introduced. A vacuum pump is connected to the vacuum chamber for the purpose of discharging the gas. The gas can be discharged with the vacuum pump so that the pressure thereof becomes 1.0×10⁻⁴ Torr or less. The electrode to which the workpiece is fixed has an electrostatic chuck function, with which it is possible to control the substrate temperature to be in a range of −30 to 120° C., and to apply a high frequency power of 13.56 MHz.

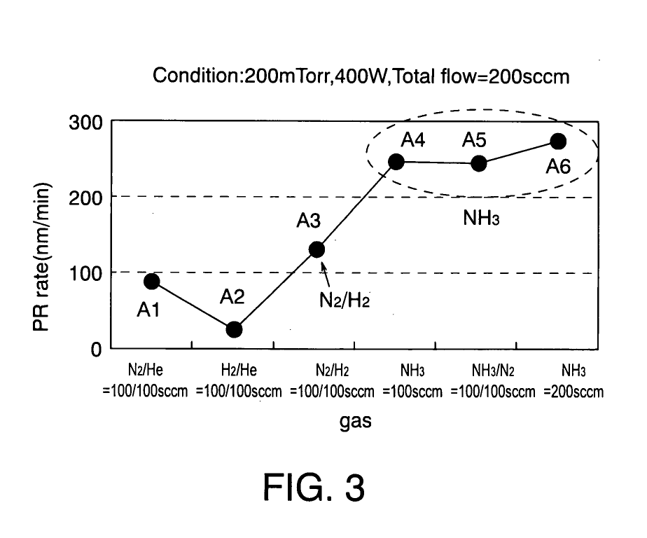

FIG. 3 shows the resist stripping rate in the cases where a gas mixture containing N₂ gas and He gas, a gas mixture containing H₂ gas and He gas, a gas mixture containing N₂ gas and H₂ gas, and gasses containing certain proportions of NH₃ gas. In FIG. 3, the horizontal axis represents the type of gas used, and the vertical axis represents the resist stripping rate. The resist stripping conditions are: the pressure of 0.2 Torr; the high frequency power of 400. W; and the NH₃ gas flow rate of 100 sccm or 200 sccm.

In FIG. 3, the point A1 represents a gas mixture containing N₂ gas and He gas (N₂:He=100 sccm:100 sccm), the point A2 represents a gas mixture containing H₂ gas and He gas (H₂:He=100 sccm:100 sccm), the point A3 represents a gas mixture containing N₂ gas and H₂ gas (N₂:H₂₌₁₀₀ sccm:100 sccm). The points A4, A5, and A6 represent gasses containing certain proportions of NH₃ gas, in which the point A4 represents the case where the gas flow rate of NH₃ gas is 100 sccm, the point A5 represents the case where NH₃:N₂₌₁₀₀ sccm:100 sccm, and the point A6 represents the case where the gas flow rate of NH₃ gas is 200 sccm.

As mentioned in the description of FIG. 10, with N₂ gas or H₂ gas, the resist stripping rate is very low, i.e., about 90 nm/min. for N₂ gas and about 20 nm/min. for H₂ gas. The resist stripping rate of the gas mixture containing N₂ gas and H₂ gas represented by the point A3 is about 120 nm/min., which is higher than that of the point A1 or A2, but is not high enough.

As can be understood from the points A4, A5, and A6, a gas containing NH₃ gas shows a high stripping rate of 250 nm/min. or more, regardless of the flow rate of NH₃ gas, and regardless of whether N₂ gas is mixed or not. That is to say, when a mixture gas containing NH₃ gas is used as a stripping gas, it is possible to obtain a stripping rate two times higher than the case where a mixture gas containing N₂ gas and H₂ gas is used.

In the resist stripping process using NH₃ gas, NH₃ is dissociated to NH₂ ion (hereinafter referred to as “NH₂⁺”) or NH ion (hereinafter referred to as “NH⁺”) as follows:
NH₃→NH₂⁺+H*, NH₂→NH⁺+H*,
where “H*” means a hydrogen radical. The NH₂⁺ ion or NH⁺ ion reacts with the resist in the following manner to strip the resist:
C+NH₂⁺ (or NH⁺)→H₂CN (or HCN).

The dissociated NH₃ reacts with methylsiloxane in the following manner:
O≡Si—CH₃+NH₂⁺ (or NH⁺)→O≡Si—CH₂—NH₂ (or O≡Si—NH₂).

When NH₃ gas is used as described above, the methylsiloxane layer 5, which is exposed, reacts with ammonium ions (NH₂⁺ or NH⁺). As a result, a protection layer 7 containing Si—N bonds or C—N bonds is formed, which can protect the methylsiloxane layer 5, as shown in FIG. 2B.

In addition, since the Si—CH₃ bonds in the methylsiloxane layer 5 do not change into Si—O bonds, the methylsiloxane layer 5 is not degraded.

When a decomposition reaction occurs to NH₃ gas, H radicals are generated, which react with each other to generate H₂. However, the volume of H₂ gas thus generated is rather small as compared with the case in which H₂ gas is introduced. Accordingly, the degradation of the low-k interlayer dielectric film is at a level that can be ignored. In order to control the generation of H₂ due to a chemical reaction or multistage dissociation of NH₃, it is effective to shorten the time a gas stays around an electrode. According to the study of the present inventor, it is preferable that the gas staying time be 10 milliseconds or less.

The gas staying time can also be shortened by adding an inert gas such as He, Ne, Ar, Kr, Xe, Rn, etc.

Next, a metal such as Cu is filled in the via hole 5a formed in the methylsiloxane layer 5, thereby forming a plug 8.

Although the method of manufacturing a semiconductor device shown in FIGS. 1A to 2C employs the semiconductor wiring formed based on a single damascene method, a dual damascene method can also be used.

For example, first, the steps as shown in FIGS. 1A to 2B are performed. Then, a resist is coated on the protection layer 7 of the semiconductor device to form a resist pattern 9 having an opening 9a to be used to form an upper layer wiring line on the via hole 5a, the opening 9a being wider than the via hole 5a.

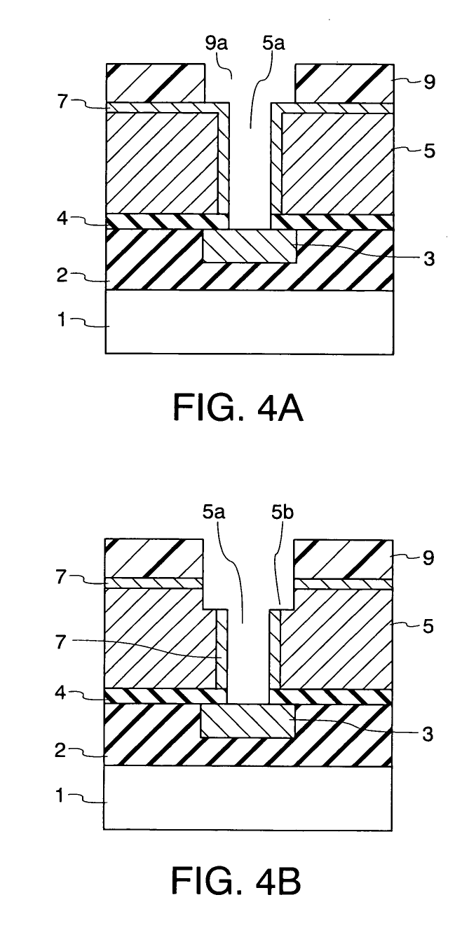

Next, as shown in FIG. 4B, the methylsiloxane layer 5 serving as the second interlayer dielectric film is etched by an RIE method using the resist pattern 9 as a mask, thereby forming a groove 5b to be used to form an upper layer wiring line on the methylsiloxane layer 5, the groove 5b being wider than the via hole 5a. The conditions for etching the methylsiloxane layer 5 can be either the same as those mentioned in the description of FIG. 2A, or different therefrom.

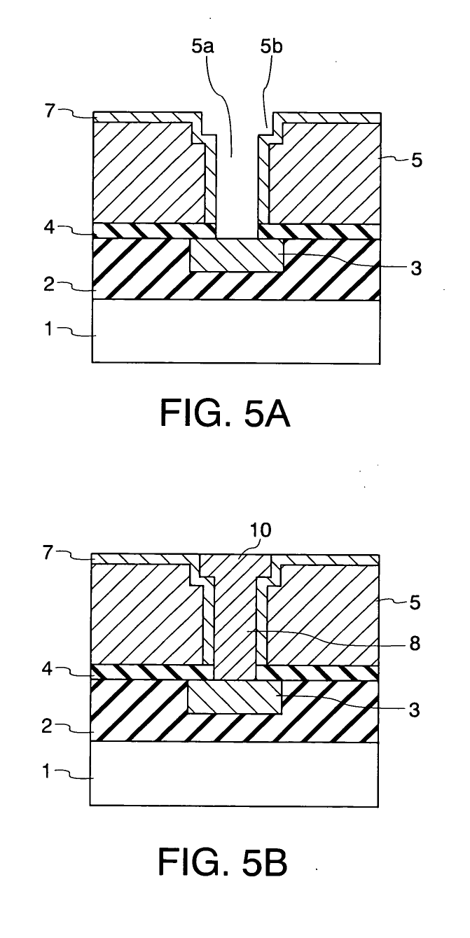

Thereafter, the unnecessary resist pattern 9 is stripped by plasma processing using NH₃ gas, in a manner similar to that already described. At this time, as shown in FIG. 5A, a protection layer 7 containing Si—N bonds or C—N bonds is formed on the surface of the groove 5b to be used to form an upper layer wiring line, as in the case of FIG. 2B. The protection layer 7 can protect the methylsiloxane layer 5.

Subsequently, as shown in FIG. 5B, a metal such as Cu is filled in the via hole 5a and the groove 5b formed in the methylsiloxane layer 5, thereby forming a plug 8 and an upper layer wiring line 10.

Instead of NH₃ gas, HCN gas or (CN)₂ gas can be used to obtain the same effect.

Ammonium ions NH⁺ can be dissociated from HCN gas due to a decomposition reaction (HCN→NH⁺+CH⁺+CN). Furthermore, ammonium ions NHₓ⁺ can be generated by adding H₂ gas from the following reaction:
HCN+H₂→NHₓ⁺+CHₓ⁺+CN.

Furthermore, ammonium ions NHx+can be generated from (CN)₂ gas with H₂ due to the following reaction: (CN)₂+H₂→NHₓ⁺+CHₓ+CN. Even if H₂ were not added, it would be possible to generate ammonium ions NHₓ⁺ from (CN)₂ due to a reaction with H contained in the resist.

As described above, a chemical reaction (C+NHₓ⁺→HₓCN) occurs to ammonium ions (NHₓ⁺) and the resist, thereby stripping the resist. Accordingly, even when HCN gas or (CN)₂ gas is used, it is possible to keep a high stripping rate since the resist is stripped by ammonium ions.

Furthermore, since it is possible to generate ammonium ions (NH⁺) from HCN gas due to a decomposition reaction, instead of mixing HCN gas and H₂ gas, it is possible to prevent Si—CH₃ bonds from changing into Si—H bonds, which have higher hydroscopic characteristics. As a result, the methylsiloxane layer is not degraded.

In addition, since ammonium ions NH⁺ can be generated as a result of a reaction between (CN)₂ gas and H contained in the resist, instead of mixing (CN)₂ gas and H₂ gas, it is possible to prevent Si—CH₃ bonds from changing into Si—H bonds, which have higher hydroscopic characteristics. As a result, the methylsiloxane layer is not degraded.

Although the low-k dielectric film serving as the second interlayer dielectric film of this embodiment is described to be formed of methylsiloxane, the material is not limited thereto, but can be a low-k material with the siloxane skeleton composition having a relative dielectric constant of 3.0 or less. For example, it is possible to form a low-k dielectric film with a silica glass containing an organic constituent such as a hydrogen siloxane, etc., which can be applied to this embodiment.

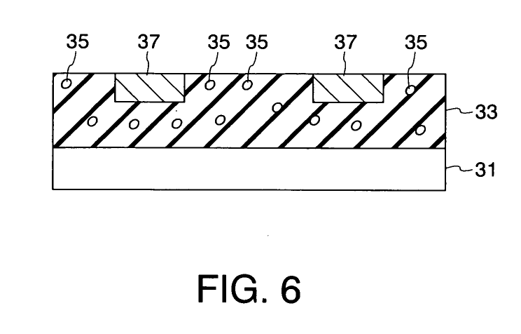

As shown in FIG. 6, a low dielectric constant can be achieved by forming a number of holes 35 in an interlayer dielectric film 33 formed on a semiconductor substrate 31, on which some elements (not shown in the drawing) are formed. If the diameter of each hole 35 were too large, the parasitic capacitance between wiring lines 37 would become large. In order to avoid this, the diameter of the hole 35 should be about 5% or less of the distance between the adjacent wiring lines 37. In the case of a semiconductor device in which the distance between the adjacent wiring lines 37 is 0.1 □m, for example, the diameter of the hole 35 should be 5 nm or less. In the modified example shown in FIG. 6, the technique of this embodiment is used to strip the resist pattern (not shown in the drawing) from the dielectric film 33, the resist pattern having been used to form grooves for wiring lines 37 in the dielectric film 33. In the modified example shown in FIG. 6, the interlayer dielectric film 33 can be formed of SiO₂.

As described above in detail, according to this embodiment, it is possible to prevent the degradation of a low-k interlayer dielectric film, and to effectively strip the resist mask deposited on the low-k dielectric film.

(Second Embodiment)

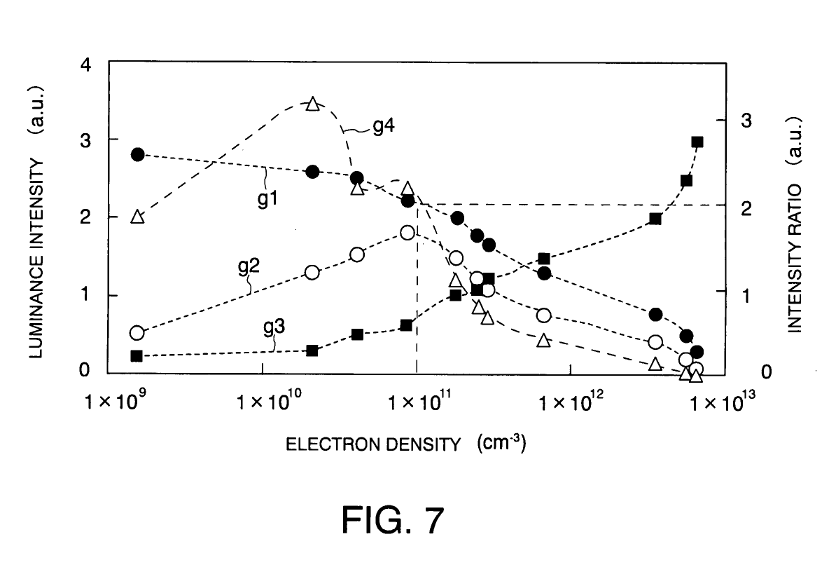

Next, a method of manufacturing a semiconductor device according to the second embodiment of the present invention will be described with reference to FIG. 7.

In the description of the first embodiment, it was mentioned that hydrogen radicals H* are formed by a decomposition reaction of NH₃ gas, and the hydrogen radicals are reacted with each other to generate H₂. Since H₂ changes the properties of a low-k dielectric film, it is effective to curb the generation of H₂ in order to avoid the degradation of a low-k dielectric film. In the second embodiment, an optimum plasma electron density is determined in order to effectively curb the generation of H₂ at the time of performing plasma processing by the use of NH₃ gas in the method of manufacturing a semiconductor device according to the first embodiment. In order to determine the optimum electron density, the following experiment was performed.

First, a capacitively coupled plasma etching apparatus was prepared to generate active species of nitrogen. The plasma etching apparatus included a pair of opposing electrodes in a chamber capable of performing vacuum discharge. One of the electrodes served as a supporting base for supporting a workpiece. A high frequency power of 13.56 MHz was applied between the electrodes via matching circuits, thereby generating an electric field. The electrode field thus generated was applied to the vacuum chamber together with a magnetic field parallel to the surface of the workpiece, which was generated by a dipole ring provided on the outer surface of the vacuum chamber. A reactive gas (in this embodiment, NH₃) was supplied to the vacuum chamber, thereby generating plasma. As a result of supplying Ar, which served as an electric discharge gas, to the plasma etching apparatus with the pressure of 40 mTorr, and the input power of 0.4 W/cm², the plasma electron density of 6.8×10¹⁰ cm⁻³ was obtained, and with the input power of 1.8 W/cm², the plasma electron density of 1.4×10¹¹ cm³ was obtained. Thus, the plasma etching apparatus was capable of controlling the plasma electron density by changing the input power.

An emission spectral measurement of NH₃ plasma was performed by the use of the aforementioned plasma etching apparatus. As a result, light emission of NH⁺ (emission wavelength: 463 nm) and H (e.g., emission wavelength: 652 nm) was confirmed. FIG. 7 shows the luminance intensity of NH₃ (line g1), ammonium ion NH⁺ (line g2), and H (line g3) and the ratio of luminance intensity between NH⁺ and H, NH⁺/H (line g4), when the plasma electron density was changed. As the plasma electron density increases, the luminance intensity of H increases, and the ratio of intensity between NH⁺ and H decreases. This occurs because as the decomposition of NH₃ gas advances, the concentration of H increases. As mentioned in the description of the first embodiment, the methyl groups in the methylsiloxane layer react with H to have a moisture-absorption property, thereby degrading the methylsiloxane layer. Accordingly, in order to remove the resist formed on the methylsiloxane layer by plasma generated from NH₃ gas without degrading the methylsiloxane layer, it is preferable that little amount of H exists.

Next, a plurality of samples were prepared, the samples having had been subjected to the manufacturing method of the first embodiment until the step shown in FIG. 2A was completed, i.e., a via hole 5a had been opened through the methylsiloxane layer 5 and the SiC layer 4 by using the resist pattern 6 having an opening 6a as a mask. Then, the step of the first embodiment shown in FIG. 2B, i.e., the step of stripping (ashing) the resist pattern 6, is performed on the samples with the plasma electron density being changed by the use of the aforementioned plasma etching apparatus. The reactive gas used during the plasma etching was NH₃ gas. Then, the emission spectral measurement of NH₃ plasma during the plasma etching was performed.

As the result of this experiment, in the case where NH₃ gas was used as the resist stripping gas, no degradation of the layer occurred when the intensity ratio between NH⁺ and H was 2 or more. That is to say, as can be understood from FIG. 7, when the plasma etching is performed so that the plasma electron density is 10¹¹ cm⁻³ or less, it is possible to curb the degradation of the methylsiloxane layer.

Thus, in the manufacturing method of this embodiment, the plasma electron density at the time of performing plasma etching by the use of NH₃ gas is set to be 10¹¹ cm⁻³ or less. As a result, it is possible to effectively perform the resist stripping by the plasma etching in which ammonium ions NHₓ⁺ are effectively generated. It is also possible to curb the degradation of the low-k dielectric film.

As a result of a further experiment, it has been known that in the case where the plasma processing is performed with HCN gas serving as a nitrogen compound gas, if the plasma electron density is set to be 10¹¹ cm⁻³ or less, it is possible to curb the generation of H₂ caused by a multistage decomposition of HCN, and to effectively curb the degradation of the methylsiloxane layer.

(Third Embodiment)

Next, the decrease in resist stripping rate, which is the problem for the plasma etching apparatus used in the manufacturing methods of the first and second embodiments, will be described. As the number of wafers being processed increases, reaction product generated as a result of reactions with resists, and metallic impurities of wiring materials, such as Cu, used in the wafers, are deposited within the processing chamber for performing the plasma etching processing. Accordingly, there is a problem in that the etchant is consumed by such deposits, thereby decreasing the resist stripping rate.

In order for the resist stripping rate to recover, there is a wet cleaning method in which the chamber is allowed to be open to the atmosphere, and the deposits on the interior parts of the apparatus are removed by using chemicals such as an alcohol and pure water. However, after performing the wet cleaning, it is necessary to perform vacuum discharge, and the plasma etching apparatus should be stopped for long period of time. As a result, the decrease in throughput is inevitable.

In contrast with this, a dry cleaning method for etching and removing deposits by the use of a reactive gas or plasma is known, as disclosed in Japanese Patent Laid-Open Publication No. 2003-124196. In this cleaning method, deposits are transformed into volatile compounds by the use of a plasma gas. However, when a metallic impurity is contained in the deposits, it is difficult to change them into volatile compounds. Accordingly, it is not possible to completely remove the deposits. At the surface of the metallic impurity, ions and radicals including hydrogen atoms are consumed due to a reduction reaction, which is a cause of the decrease in resist stripping rate.

In this embodiment, a method of cleaning a plasma etching apparatus using of plasma is proposed in order to prevent the decrease in resist stripping rate.

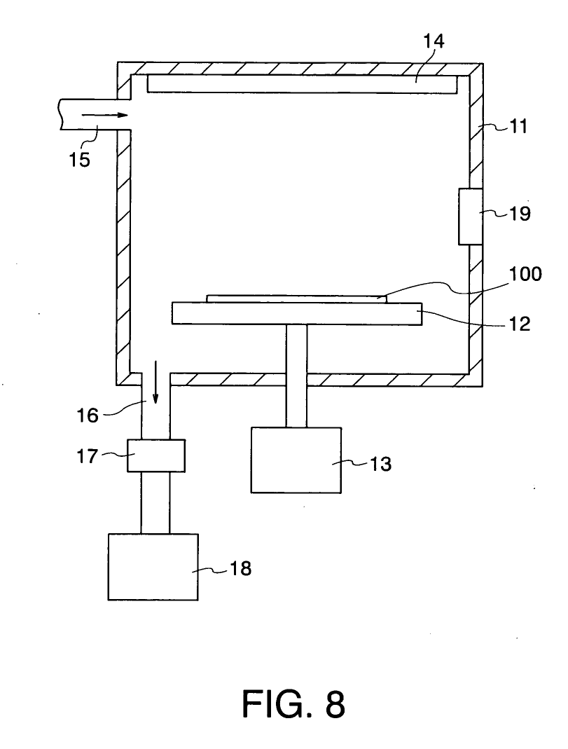

Hereinafter a method of cleaning a plasma etching apparatus according to the third embodiment of the present invention will be described. FIG. 8 shows a plasma etching apparatus to which the cleaning method of this embodiment is applied. This plasma etching apparatus is a parallel flat plate type RIE apparatus including a stage 12 in a vacuum chamber 11. A wafer 100 is mounted and fixed on the stage 12. The stage 12 serves as an electrode, to which a high frequency power supply 13 of, e.g., 13.56 MHz is connected. Another electrode 14 is mounted on the upper portion of the interior wall of the vacuum chamber 11 so as to oppose the stage 12. The electrode 14 is connected to a ground. A predetermined flow rate of a reactive gas is supplied to the vacuum chamber 11 from a gas supply port 15. The pressure within the vacuum chamber 11 is kept at a predetermined level by a vacuum pump 18 via an opening degree adjusting valve 17 connected to a gas discharge tube 16. The reactive gas is excited by a predetermined level of a high frequency voltage being applied across the electrodes 12 and 14, thereby creating plasma above the stage 12. A window 19 is provided on the side wall of the vacuum chamber 11, through which it is possible to perform a plasma emission and spectral measurement. A material, such as alumina, quartz, etc., is used to form the interior walls of the vacuum chamber 11 so that the interior walls do not react with the excited gas.

The resist stripping rate (ashing rate) of this plasma etching apparatus was measured in the case where O₂ was used as the reactive gas, and the case where NH₃ was used as the reactive gas. When O₂ was used (the O₂ gas flow rate set at 200 sccm; the pressure at 20 Pa; and the RF power at 500 W), the rate was 550 nm/min., and when NH₃ was used (the NH₃ gas flow rate set at 400 sccm; the pressure at 30 Pa; and the RF power at 600 W), the rate was 250 nm/min.

Then, the resist stripping processing in the process of manufacturing a semiconductor device including a low-k dielectric film according to, e.g., the first embodiment, was performed by the use of this plasma etching apparatus. During the stripping steps at the time when the low-k dielectric film is exposed (for example, the step of stripping the resist pattern 6 in the first embodiment), NH₃ gas was used as the reactive gas, and during the other stripping steps (for example, the step of stripping the resist after the formation of grooves to be used to form the lower wiring lines 3 in the first interlayer dielectric film 2), O₂ gas was used as the reactive gas. For the respective resist stripping steps, the resist ashing rates were measured to monitor the changes in ashing rate. As the result, both the ashing rate of O₂ and the ashing rate of NH₃ were gradually increased until about 500 nm/min. for O₂ and about 190 nm/min. for NH₃. Thereafter, the ashing rates were stabilized.

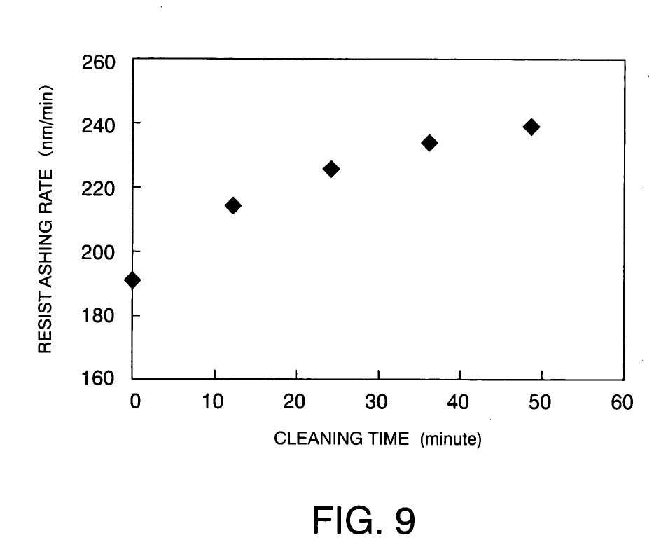

Next, a dummy Si wafer was mounted on the stage 12, and the dry cleaning processing of the aforementioned plasma etching apparatus was performed, using NH₃ gas as a cleaning gas. After the cleaning processing of the plasma etching apparatus, the resist stripping step was performed on a semiconductor device including a low-k dielectric film. During the stripping steps at the time when the low-k dielectric film was exposed, NH₃ gas was used as the reactive gas, and during the other stripping steps, O₂ gas was used as the reactive gas. Thereafter, the stripping step was performed on another semiconductor device including a low-k dielectric film. This was repeated until the resist ashing rate, which had been decreasing, became stable. At this time, the aforementioned cleaning processing was performed with the cleaning time being changed. The whole process was repeated several times. The result of this experiment is shown in FIG. 9.

FIG. 9 shows the relationship between the dry cleaning time and the resist ashing rate when NH₃ gas is used as an ashing gas. In FIG. 9, the horizontal axis represents the cleaning time, i.e., the plasma discharge time during the cleaning processing, and the vertical axis represents the resist ashing rate. As can be understood from FIG. 9, as the cleaning time increases, the resist ashing rate increases. After the cleaning time of 48 minutes has passed, the resist ashing rate reaches 240 nm/min., recovering to a level before the ashing rate started decreasing. In the case where O₂ gas is used as the ashing gas after the cleaning time of 48 minutes, the ashing rate reaches about 550 nm/min., a level before the ashing rate started decreasing.

Next, a similar experiment was performed using O₂ gas as the cleaning gas, instead of NH₃ gas. When O₂ gas was used as the cleaning gas, the ashing rate in the stripping steps in which O₂ gas was used as the resist ashing gas recovered, but the ashing rate in the stripping steps in which NH₃ gas was used as the resist ashing gas did not recover. The reason for this may be as follows. When O₂ gas is used as the cleaning gas, oxygen ions react with organic constituents in the deposits within the vacuum chamber of the plasma etching apparatus, and change into volatile substances such as CO, CO₂, H₂O, etc. Then such volatile substances can be removed. After a sufficient level of cleaning is performed, reactive constituents of the deposits in the vacuum chamber are removed, resulting in that oxygen ions are not consumed anymore. Because of this, the ashing rate recovers in the case where O₂ gas is used as the ashing gas. In contrast with this, the reason why the ashing rate does not recover in the stripping steps using NH₃ gas as the ashing gas may be that although ammonium ions are not consumed by the organic constituents of the deposits, ammonium ions are further consumed by a metallic impurity, such as Cu, which has remained in the deposits, in a reduction reaction.

However, when NH₃ gas is used as the cleaning gas as in the case of this embodiment, ammonium ions remove the organic constituents in the deposits, and also reduce the metal impurity. Accordingly, ammonium ions are not consumed anymore. As the result, the ashing rate in the stripping steps using NH₃ gas as an ashing gas is recovers.

After the ashing rate was decreased, the vacuum chamber was actually allowed to be open to the atmosphere to observe the inside thereof. As a result, the adhesion of deposits was observed in the vacuum chamber, especially around the wafer periphery portion. After the cleaning was performed again using O₂ gas as the cleaning gas, the vacuum chamber was opened to the atmosphere again. As the result, most of the deposits remained. In contrast with this, after the cleaning was performed again using NH₃ gas as the cleaning gas, most of the deposits were removed. It can be understood from this that the deposits contain a considerable amount of metallic impurities, such as Cu, and due to this fact, it is not possible to remove the deposits during a cleaning step using O₂ gas. The removal of the deposits can be achieved by performing a cleaning step using NH₃ gas as the cleaning gas. The reason for this may be that Cu reacts with NH₃ to create a complex Cu(NH₃)₄, which can be etched.

In this embodiment, the cleaning was performed after the resist stripping step was performed without performing the dry cleaning at all, resulting in that a considerable amount of deposits were created, thereby decreasing the ashing rate to the lowest level. Accordingly, the time required for the cleaning step was relatively long. However, the degree of the change in ashing rate, and the cleaning time can be decreased by performing the cleaning processing whenever a certain amount of deposits are created.

Although a parallel flat plate type RIE apparatus was used in this embodiment, a plasma etching apparatus in which microwaves or a inductively coupled plasma source is combined with a source plasma can also be used. Furthermore, as in the case of the first and second embodiments, an inert gas such as He, Ne, Ar, Kr, Xe, Rn, etc., can be added to curb the plasma electron density to be 10¹¹ cm⁻³ or less. This is very effective for generating ammonium ions with the generation of H₂ being curbed.

It is possible to easily overcome the decrease in ashing rate caused by the deposits adhering to the interior walls of the vacuum chamber by performing the dry cleaning of the vacuum chamber with plasma generated by using HN₃ gas after the resist ashing processing is performed. Since the cleaning frequency can be decreased in this manner, the operation rate of the plasma etching apparatus can be improved, thereby increasing the productivity.

As described above, according to the embodiments of the present invention, it is possible to avoid the degradation of a low-k dielectric film, and to effectively strip a resist mask deposited on the low-k dielectric film.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concepts as defined by the appended claims and their equivalents.

1. A method of manufacturing a semiconductor device comprising:
forming a low-k dielectric film above a semiconductor substrate;
forming a resist pattern above the low-k dielectric film;
etching the low-k dielectric film using the resist pattern as a mask; and
stripping the resist pattern by plasma processing using ammonium ions.

2. The method of manufacturing a semiconductor device according to claim 1, wherein the stripping of the resist pattern includes adding an inert gas selected from the group consisting of He, Ne, Ar, Kr, Xe, and Rn during the plasma processing.

3. The method of manufacturing a semiconductor device according to claim 1, wherein the low-k dielectric film has a siloxane skeleton composition.

4. The method of manufacturing a semiconductor device according to claim 1, wherein the low-k dielectric film is a silica glass film containing an organic constituent.

5. The method of manufacturing a semiconductor device according to claim 1, wherein the low-k dielectric film is formed of methylpolysiloxane.

6. The method of manufacturing a semiconductor device according to claim 1, further comprising forming a plurality of wiring lines in the low-k dielectric film, wherein the low-k dielectric film includes holes, a diameter of each hole being 5% or less of a distance between the wiring lines.

7. The method of manufacturing a semiconductor device according to claim 6, wherein the diameter of each hole is 5 nm or less.

8. The method of manufacturing a semiconductor device according to claim 1, further comprising forming wiring lines of a metal above the semiconductor substrate before the forming of the low-k dielectric film, wherein the etching of the low-k dielectric film results in forming a hole for connection to the wiring lines.

9. A method of manufacturing a semiconductor device comprising:
forming a low-k dielectric film above a semiconductor substrate;
forming a resist pattern above the low-k dielectric film;
etching the low-k dielectric film using the resist pattern as a mask; and
stripping the resist pattern by plasma processing using nitrogen active species obtained by exciting a nitrogen compound gas selected from the group consisting of NH₃ and HCN by using plasma, an electron density of the plasma being 1×10¹¹ cm⁻³ or less.

10. The method of manufacturing a semiconductor device according to claim 9, wherein the stripping of the resist pattern includes adding an inert gas selected from the group consisting of He, Ne, Ar, Kr, Xe, and Rn during the plasma processing.

11. The method of manufacturing a semiconductor device according to claim 9, wherein the low-k dielectric film has a siloxane skeleton composition.

12. The method of manufacturing a semiconductor device according to claim 9, wherein the low-k dielectric film is a silica glass film containing an organic constituent.

13. The method of manufacturing a semiconductor device according to claim 9, wherein the low-k dielectric film is formed of methylpolysiloxane.

14. The method of manufacturing a semiconductor device according to claim 9, further comprising forming a plurality of wiring lines in the low-k dielectric film, wherein the low-k dielectric film includes holes, a diameter of each hole being 5% or less of a distance between the wiring lines.

15. The method of manufacturing a semiconductor device according to claim 14, wherein the diameter of each hole is 5 nm or less.

16. The method of manufacturing a semiconductor device according to claim 9, further comprising forming wiring lines of a metal above the semiconductor substrate before the forming of the low-k dielectric film, wherein the etching of the low-k dielectric film results in forming a hole for connection to the wiring lines.

17. The method of manufacturing a semiconductor device according to claim 9, wherein the plasma processing uses ammonium ions as the nitrogen active species.

18. A method of cleaning a plasma etching apparatus in which a resist formed on a surface of a substrate is stripped by plasma etching performed in a vacuum chamber, the method comprising:
supplying NH₃ gas to the vacuum chamber; and
generating plasma in the vacuum chamber and removing deposits adhering to the inside of the vacuum chamber.

19. The method of cleaning a plasma etching apparatus according to claim 18, wherein the plasma etching apparatus is a parallel flat plate type RIE apparatus.

20. The method of cleaning a plasma etching apparatus according to claim 18, wherein in the plasma etching apparatus, microwaves or a inductively coupled plasma source is combined with a source plasma.
